(19) United States
(12) Patent Application Publication
(10) Pub. No.: US 2026/0322350 A1
(43) Pub. Date: Oct. 15, 2026

(54) SURFACE ACOUSTIC WAVE DEVICE WITH ROUGHENED SUPPORT SUBSTRATE

(71) Applicant: Skyworks Solutions, Inc., Irvine, CA (US)

(72) Inventors: David Albert Feld, Los Altos, CA (US); Rei Goto, Osaka-Shi (JP)

(21) Appl. No.: 19/465,759

(22) Filed: Jan. 30, 2026

Related U.S. Application Data
(60) Provisional application No. 63/752,493, filed on Jan. 31, 2025.
(60) Provisional application No. 63/752,486, filed on Jan. 31, 2025.

(51) Int. Cl. H03H 9/05; H03H 3/08; H03H 9/145

(52) U.S. Cl. CPC H03H 9/058; H03H 3/08; H03H 9/14538

(57) ABSTRACT

A surface acoustic wave device has a support substrate with a first side having a surface roughness greater than a surface roughness of the second side. A piezoelectric layer is over the second side of the support substrate and an interdigital transducer electrode is in electrical communication with the piezoelectric layer.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Technical Field

Embodiments of this disclosure relate to acoustic wave devices, and in particular, to multi-layer piezoelectric substrate surface acoustic wave (MPS-SAW) devices.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed.

There can be unwanted responses generated in a SAW device, including nonlinearity, which distorts the signal by producing harmonics, intermodulation products, and spurious signals not present in the original input. These effects degrade device performance by reducing signal fidelity and creating interference. In high-precision applications like telecommunications and signal processing, minimizing nonlinearity is crucial to maintain optimal performance, making it a key design goal for SAW devices.

### SUMMARY

In some aspects, the techniques described herein relate to a surface acoustic wave device including: a support substrate having a first side and second side, the first side having a surface roughness greater than a surface roughness of the second side; a piezoelectric layer over the second side of the support substrate; and an interdigital transducer electrode in electrical communication with the piezoelectric layer.

In some aspects, the techniques described herein relate to a surface acoustic wave device wherein the surface roughness of the first side is in a range between 100 nanometers and 1000 nanometers.

In some aspects, the techniques described herein relate to a surface acoustic wave device wherein the surface roughness of the first side is in a range between 100 nanometers and 750 nanometers.

In some aspects, the techniques described herein relate to a surface acoustic wave device wherein the surface roughness of the first side is in a range between 200 nanometers and 750 nanometers.

In some aspects, the techniques described herein relate to a surface acoustic wave device wherein the surface roughness of the first side is 10 to 10000 times greater than the surface roughness of the second side.

In some aspects, the techniques described herein relate to a surface acoustic wave device wherein the surface roughness of the first side is 100 to 10000 times greater than the surface roughness of the second side.

In some aspects, the techniques described herein relate to a surface acoustic wave device wherein the first side of the support substrate includes grooves.

In some aspects, the techniques described herein relate to a surface acoustic wave device wherein the grooves have a curvature.

In some aspects, the techniques described herein relate to a surface acoustic wave device wherein the grooves have a random pattern.

In some aspects, the techniques described herein relate to a surface acoustic wave device wherein the support substrate includes a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, or an aluminum oxide layer.

In some aspects, the techniques described herein relate to a surface acoustic wave device further including an intermediate structure between the support substrate and the piezoelectric layer.

In some aspects, the techniques described herein relate to a surface acoustic wave device wherein the intermediate structure includes a trap-rich layer.

In some aspects, the techniques described herein relate to a surface acoustic wave device wherein the intermediate structure includes a functional layer.

In some aspects, the techniques described herein relate to a surface acoustic wave device including: a support substrate having a first side and second side, the first side having a surface roughness in a range between 100 nanometers and 1000 nanometers; a piezoelectric layer over the second side of the support substrate; and an interdigital transducer electrode in electrical communication with the piezoelectric layer.

In some aspects, the techniques described herein relate to a surface acoustic wave device wherein the surface roughness of the first side is 10 to 10000 times greater than the surface roughness of the second side.

In some aspects, the techniques described herein relate to a surface acoustic wave device further including an intermediate structure between the support substrate and the piezoelectric layer, wherein the intermediate structure includes a trap-rich layer and a functional layer.

In some aspects, the techniques described herein relate to a surface acoustic wave die including: a support substrate having a first side and second side, the first side having a surface roughness greater than a surface roughness of the second side; a piezoelectric layer over the second side of the support substrate; and a plurality of interdigital transducer electrodes in electrical communication with the piezoelectric layer.

In some aspects, the techniques described herein relate to a surface acoustic wave die wherein the surface roughness of the first side is in a range between 100 nanometers and 1000 nanometers.

In some aspects, the techniques described herein relate to a surface acoustic wave die wherein the plurality of interdigital transducer electrodes include two to fifty interdigital transducer electrodes.

In some aspects, the techniques described herein relate to a surface acoustic wave die is an acoustic wave filter.

In some aspects, the techniques described herein relate to a method of manufacturing a surface acoustic wave device, the method including: providing a multi-layer piezoelectric substrate including a support substrate having a first side and second side and a piezoelectric layer over the second side of the support substrate; forming an interdigital transducer electrode in electrical communication with the piezoelectric layer; and roughening the first side of the support substrate to make a surface roughness of the first side greater than a surface roughness of the second side.

In some aspects, the techniques described herein relate to a method wherein roughening the first side of the support substrate includes grinding.

In some aspects, the techniques described herein relate to a method wherein roughening the first side of the support substrate makes the surface roughness of the first side to be in a range between 100 nanometers and 1000 nanometers.

In some aspects, the techniques described herein relate to a method wherein roughening the first side of the support substrate makes the surface roughness of the first side to be in a range between 100 nanometers and 750 nanometers.

In some aspects, the techniques described herein relate to a method wherein roughening the first side of the support substrate makes the surface roughness of the first side to be in a range between 200 nanometers and 750 nanometers.

In some aspects, the techniques described herein relate to a method wherein roughening the first side of the support substrate makes the surface roughness of the first side to be in a range between 10 to 10000 times greater than the surface roughness of the second side.

In some aspects, the techniques described herein relate to a method wherein roughening the first side of the support substrate makes the surface roughness of the first side to be in a range between 100 to 10000 times greater than the surface roughness of the second side.

In some aspects, the techniques described herein relate to a method wherein roughening the first side of the support substrate includes forming grooves on the first side of the support substrate.

In some aspects, the techniques described herein relate to a method wherein the support substrate includes a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, or an aluminum oxide layer.

In some aspects, the techniques described herein relate to a method wherein the multi-layer piezoelectric substrate further includes an intermediate structure between the support substrate and the piezoelectric layer.

In some aspects, the techniques described herein relate to a method wherein the intermediate structure includes a trap-rich layer.

In some aspects, the techniques described herein relate to a method wherein the intermediate structure includes a functional layer.

In some aspects, the techniques described herein relate to a method further including singulating the surface acoustic wave device after roughening the first side of the support substrate.

In some aspects, the techniques described herein relate to a method of manufacturing a surface acoustic wave device, the method including: providing a multi-layer piezoelectric substrate including a support substrate having a first side and second side and a piezoelectric layer over the second side of the support substrate; forming an interdigital transducer electrode in electrical communication with the piezoelectric layer; and grinding the first side of the support substrate to make a surface roughness of the first side greater than a surface roughness of the second side.

In some aspects, the techniques described herein relate to a method wherein grinding the first side of the support substrate makes the surface roughness of the first side to be in a range between 100 nanometers and 1000 nanometers.

In some aspects, the techniques described herein relate to a method wherein grinding the first side of the support substrate makes the surface roughness of the first side to be in a range between 10 to 10000 times greater than the surface roughness of the second side.

In some aspects, the techniques described herein relate to a method wherein grinding the first side of the support substrate makes the surface roughness of the first side to be in a range between 100 to 10000 times greater than the surface roughness of the second side.

In some aspects, the techniques described herein relate to a method wherein grinding the first side of the support substrate includes forming grooves on the first side of the support substrate.

In some aspects, the techniques described herein relate to a method of manufacturing a surface acoustic wave device, the method including: providing a multi-layer piezoelectric substrate including a support substrate having a first side and second side and a piezoelectric layer over the second side of the support substrate; forming an interdigital transducer electrode in electrical communication with the piezoelectric layer; and making a surface roughness of the first side to be in a range between 100 nanometers and 1000 nanometers.

In some aspects, the techniques described herein relate to a method further including singulating the surface acoustic wave device after making the surface roughness of the first side to be in the range between 100 nanometers and 1000 nanometers.

### BRIEF DESCRIPTION OF THE DRAWINGS

Embodiments of this disclosure will now be described, by way of non-limiting example, with reference to the accompanying drawings.

FIG. 1 is a schematic cross-sectional side view of a surface acoustic wave (SAW) device.

FIG. 2 is a schematic cross-sectional side view of a SAW device according to an embodiment.

FIG. 3A is a graph showing example wave form.

FIG. 3B is a graph showing simulated wave forms of the SAW device of FIG. 1 and the SAW device of FIG. 2.

FIG. 4 is a schematic cross-sectional side view of a SAW device according to an embodiment.

FIG. 5A is a schematic cross-sectional side view of an acoustic wave device structure that includes a support substrate prior to roughening.

FIG. 5B is a schematic cross-sectional side view of the structure of FIG. 5A after roughening.

FIG. 6A is a schematic diagram of a transmit filter that includes a surface acoustic wave resonator according to an embodiment.

FIG. 6B is a schematic diagram of a receive filter that includes a surface acoustic wave resonator according to an embodiment.

FIG. 7 is a schematic diagram of a radio frequency module that includes a surface acoustic wave resonator according to an embodiment.

FIG. 8 is a schematic diagram of a radio frequency module that includes filters with surface acoustic wave resonators according to an embodiment.

FIG. 9 is a schematic block diagram of a module that includes an antenna switch and duplexers that include a surface acoustic wave resonator according to an embodiment.

FIG. 10A is a schematic block diagram of a module that includes a power amplifier, a radio frequency switch, and duplexers that include a surface acoustic wave resonator according to an embodiment.

FIG. 10B is a schematic block diagram of a module that includes filters, a radio frequency switch, and a low noise amplifier according to an embodiment.

FIG. 11A is a schematic block diagram of a wireless communication device that includes a filter with a surface acoustic wave resonator in accordance with one or more embodiments.

FIG. 11B is a schematic block diagram of another wireless communication device that includes a filter with a surface acoustic wave resonator in accordance with one or more embodiments.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. SAW devices include SAW resonators, SAW delay lines, and multi-mode SAW (MMS) filters (e.g., double-mode SAW (DMS) filters). Although embodiments may be discussed with reference to SAW resonators, the principles and advantages discussed herein can be applied to any suitable SAW device and/or any suitable acoustic wave device.

Acoustic wave filters can include SAW resonators that include a multi-layer piezoelectric substrate. Multi-layer piezoelectric substrates can provide good thermal dissipation characteristics and improved temperature coefficient of frequency (TCF) relative to certain single layer piezoelectric substrates. For example, a SAW resonator with a piezoelectric layer on a high impedance support substrate, such as silicon, can achieve better temperature coefficient of frequency (TCF) and thermal dissipation compared to a similar device without the high impedance support substrate.

For example, a SAW resonator can include a silicon dioxide (SiO₂) layer, a lithium niobate (LN) piezoelectric layer, an interdigital transducer (IDT) over the LN piezoelectric layer, and a high impedance support substrate (e.g., a silicon substrate) under the LN piezoelectric layer. Such resonators with the high impedance substrate can be beneficial for obtaining a better TCF and/or a better thermal dissipation characteristic than temperature compensated (TC) SAW resonators that do not include the high impedance substrate structure.

However, SAW resonators that include a piezoelectric layer on certain high impedance support substrates can experience spurious responses as a result of back reflection from the high impedance support substrate. This can degrade a frequency response of a filter that includes the SAW resonators. For example, back reflection from a surface of the support substrate that faces the piezoelectric layer can cause spurious responses at or near the third order harmonic, and back reflection from a surface of the support substrate that faces away the piezoelectric layer can cause spurious responses at or near the fourth order harmonic.

The back reflection from the support substrate can also cause nonlinearity in the frequency response. Reduced nonlinearity can be desirable in some SAW devices as it can affect the performance (e.g., the quality factor) of the SAW devices. Nonlinearity in SAW devices can be the deviation from a proportional relationship between the input signal and the output response, which can result in signal distortion and unwanted harmonics. Improving nonlinearity can be important because it enhances the device's performance by reducing signal degradation, maintaining signal integrity, and ensuring high-fidelity transmission, which can be significant in applications like telecommunications and signal processing. Nonlinear behavior can cause higher-order modes, such as third-order harmonics, to appear, which are multiples of the fundamental frequency and further degrade the signal quality in some applications. Therefore, there is a need for nonlinearity improvement in SAW devices to achieve optimal performance and reliable operation in critical applications.

Aspects of this disclosure relate to SAW devices with a support substrate that prevents or suppress formation of the spurious responses and the nonlinearity due to back reflection from a surface of the support substrate that faces away the piezoelectric layer. Embodiments of SAW devices disclosed herein can include a multi-layer piezoelectric substrate including a piezoelectric layer and a support substrate. The multi-layer piezoelectric substrate can also include an intermediate structure having one or more of a functional layer, a trap-rich layer, or a seed layer. The support substrate can have a first side and second side. The first side having a surface roughness greater than a surface roughness of the second side. The First side of the support substrate can face away the piezoelectric layer and the second side of the support substrate can face the piezoelectric layer. The surface roughness of the first side can be in a range between 100 nanometers and 1000 nanometers. The surface roughness of the first side can be 10 to 10000 times greater than the surface roughness of the second side. The first side of the support substrate can be roughened by way of grinding.

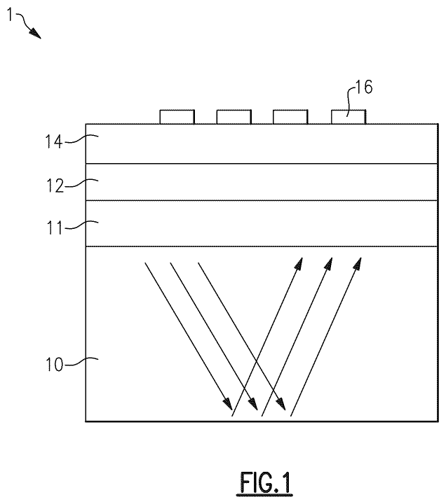

FIG. 1 is a schematic cross-sectional side view of a surface acoustic wave (SAW) device 1. The SAW device 1 includes a support substrate 10, intermediate layers 11, 12, a piezoelectric layer 14, and an interdigital transducer (IDT) electrode 16. The wave generated by the IDT electrode 16 can reflect back from a bottom surface of the support substrate 10 and the reflected wave can interfere with the desired wave form of the SAW device 1 and can cause spurious responses and the nonlinearity.

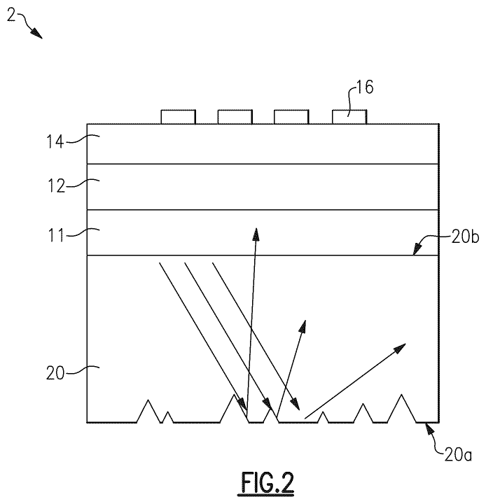

FIG. 2 is a schematic cross-sectional side view of a SAW device 2 according to an embodiment. The SAW device 2 is an example of a multi-layer piezoelectric substrate (MPS) SAW device. The SAW device 2 can include a support substrate 20, an intermediate structure including intermediate layers 11, 12, a piezoelectric layer 14, and an interdigital transducer (IDT) electrode 16. The intermediate structure can be positioned between the support substrate 20 and the piezoelectric layer 14. The support substrate 20 and the intermediate structure can together define a support structure, and the support structure and the piezoelectric layer 14 can together define the MPS. The interdigital transducer electrode 16 can be in electrical communication with the piezoelectric layer 14.

The support substrate 20 can have a relatively high acoustic impedance. For example, the support substrate 20 can have a higher impedance than an impedance of the piezoelectric layer 14 and a higher thermal conductivity than a thermal conductivity of the piezoelectric layer 14. The support substrate 20 can be a silicon substrate, for example. The support substrate 20 can be any suitable substrate layer, such as a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, or the like. The support substrate 20 can include a dielectric material. For example, the support substrate 20 can include sapphire or aluminum oxide (Al₂O₃). As compared to some other materials, such as silicon, sapphire has lower or no parasitic surface conductance as sapphire is dielectric. The multilayer piezoelectric substrate (MPS) that includes a sapphire support substrate can be referred to as a sapphire MPS.

The support substrate 20 has a first side 20a and the second side 20b opposite the first side. The first side 20a can face away the piezoelectric layer 14 and the second side 20b can face the piezoelectric layer 14. The second first side 20a of the support substrate 20 can have a sufficiently rough surface that can scatter an incident wave. In some embodiments, the first side 20a can have a surface roughness that is greater than a surface roughness of the second side 20b. The surface roughness can be an average surface roughness of the second side 20a of the support substrate 20 in an area below the interdigital transducer electrode 16. For example, the surface roughness of the first side 20a can be 10 to 10000 times greater or 100 to 10000 times greater than the surface roughness of the second side 20b. In some embodiments, the surface roughness of the first side can be in a range between 100 nanometers and 1000 nanometers, 100 nanometers and 750 nanometers, or 200 nanometers and 750 nanometers.

In some embodiments, the first side 20a of the support substrate 20 can be roughened by way of grinding. For example, the grinding process can utilize a grinding wheel or grinding disc to grind the first side 20a of the support substrate 20. A grit size or mesh size of the grinding wheel or grinding disc can be sufficiently rough to roughen the first side 20a of the support substrate 20 in the surface roughness ranges disclosed herein. The grinding process can form grooves on first side 20a of the support substrate 20. Due to the grinding process, the grooves can have a curvature. In some embodiments, the grooves can have a random pattern. Because the grinding process for grinding the first side 20a of the support substrate 20 roughens the first side 20a, the process can be referred to a coarse grinding process.

The second side 20b of the support substrate 20 can be relatively smooth. For example, the second side 20b of the support substrate 20 can be sufficiently smooth to provide a sufficient bonding strength between the second side 20b of the support substrate 20 and the intermediate structure (e.g., the intermediate layer 11 and/or 12).

The intermediate layer 11 can be, for example, a trap-rich layer that can suppress the parasitic surface conductivity at a surface of the support substrate 20 while improving the quality factor (Q) as compared to a similar device without a trap-rich layer. In some embodiments, the intermediate layer 11 can be a polycrystalline silicon layer. In some embodiments, the intermediate layer 11 can be a doped region of the support substrate 20.

The intermediate layer 12 can be, for example, a single crystal layer. In some embodiments, the intermediate layer 12 can be a silicon oxide layer (e.g., a silicon dioxide (SiO₂) layer. In some embodiment, the intermediate layer 12 can function as an adhesion layer. In some embodiments, a thickness of the intermediate layer 12 can be the same as, generally similar to, or thinner than the thickness of the piezoelectric layer 14.

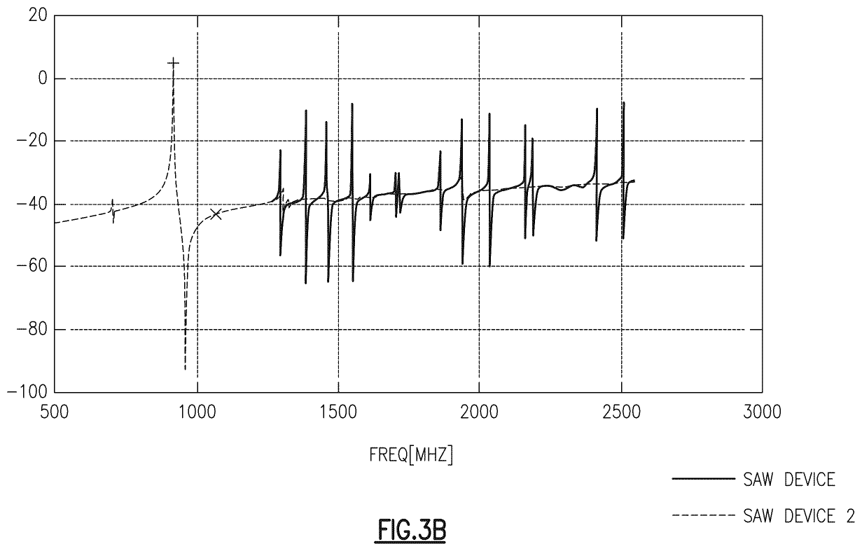

The intermediate layer(s) 11 and/or 12 can be omitted, in some embodiments. For example, depending on the material of the support substrate 20, the intermediate layer(s) 11 and/or 12 can be omitted (see FIG. 4).

The piezoelectric layer 14 can include any suitable piezoelectric layer, such as a lithium based piezoelectric layer. Example lithium based piezoelectric materials include lithium tantalate and lithium niobate. In some embodiments, the piezoelectric layer 14 can be a lithium tantalate (LT) layer. For example, the piezoelectric layer 14 can be an LT layer having a cut angle of 20° (20° Y-cut X-propagation LT), a cut angle of 60° (60° Y-cut X-propagation LT), or a cut angle in a range from 20° to 60°. For example, the piezoelectric layer 14 can be 20±10° Y-cut LT, 42±25° Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 14. For example, the piezoelectric layer 14 can be an LN layer having a cut angle of about 118° (118° Y-cut X-propagation LN) or more or a cut angle of about 132° (132 Y-cut X-propagation LN) or less. For example, the piezoelectric layer 14 can be 125±20° Y-cut LN, 125±15° Y-cut LN, 125±10° Y-cut LN, or 125±5° Y-cut LN. A thickness of the piezoelectric layer 14 can be selected based on a wavelength λ or L of a surface acoustic wave generated by the acoustic wave device 3 in certain applications. In some embodiments, the wavelength L can be in a range between, for example, 3 micrometers and 6 micrometers, 3.5 micrometers and 6 micrometers, 3 micrometers and 5.5 micrometers, or 3.5 micrometers and 5.5 micrometers. The piezoelectric layer 14 can be sufficiently thick to avoid significant frequency variation. For example, the thickness of the piezoelectric layer 14 can be in a range of 0.1 L to 0.5 L, 0.1 L to 0.3 L, or 0.1 L to 0.2 L. Selecting the thickness of the piezoelectric layer 14 from these ranges can be significant in avoiding significant frequency variation and providing sufficient temperature coefficient of frequency for the SAW device 2. In some embodiments, the piezoelectric layer 14 can include lithium tantalate (LT) and lithium niobate (LN).

The IDT electrode 16 can include any suitable IDT electrode material. For example, the electrodes can include molybdenum (Mo), aluminum (Al), copper (Cu), Magnesium (Mg), titanium (Ti), tungsten (W), the like, or any suitable combination thereof. The IDT electrode 16 can have a multilayer structure. One of the first layer and the second layer can be more electrically conductive than the other, and the other one can be more durable (e.g., resistive to metal fatigue). In some embodiments, the first layer or the second layer can have a higher mass density and/or higher Young's modulus than the other. The IDT electrode 16 can be formed with (e.g., formed on or at least partially in) the piezoelectric layer 14. The piezoelectric layer 14 and the IDT electrode 16 can be provided in any suitable manner. For example, the piezoelectric layer 14 and the IDT electrode 16 can be provided in sequence. When the IDT electrode 16 is provided at least partially in the piezoelectric layer 14, the piezoelectric layer 14 can be partially etched and/or provided in a plurality of steps.

The SAW device 2 shown in FIG. 2 can be a portion of a larger device or die. For example, the SAW device 2 can be one of a plurality of resonators (e.g., 2 to 50 resonators) included in an acoustic wave device or die, such as a filter die. The plurality of resonators can share the support substrate 20. There may be one or more capacitors (e.g., IDT capacitors) included in the acoustic wave device or die.

The roughened surface of the first side 20a of the support substate 20 can be beneficial for preventing or suppressing formation of spurious responses at higher harmonics (e.g., the fourth harmonic). The roughened surface of the first side 20a of the support substate 20 can eliminate or reduce nonlinearity in the SAW device 2.

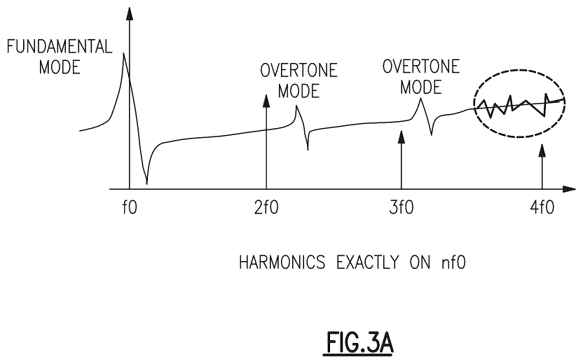

FIG. 3A is a graph showing an example wave form. The wave form can represent a wave form that can be generated by the SAW device 2. The graph also shows location of the frequency response that can be affected by the back reflection from the bottom surface of the support substrate 10 of the SAW device 1. FIG. 3A indicates that, in the circled region at or near the fourth harmonic, spurious response in the form of ripples can be formed in the SAW device 1. Such spurious response can be suppressed in the SAW device 2.

FIG. 3B is a graph showing simulated wave forms of the SAW device 1 and the SAW device 2. FIG. 3B indicates that the SAW device 2 with the roughened surface can provide a cleaner wave form with less spurious as compared to the SAW device 1.

The benefits of the roughened surface of the first side 20a of the support substrate 20 can be realized even without the intermediate layer(s) 11 and/or 12. For example, the intermediate layer 11 can be omitted as shown in FIG. 4.

FIG. 4 is a schematic cross-sectional side view of a SAW device 4 according to an embodiment. Unless otherwise noted, components shown in FIG. 4 may be structurally and/or functionally the same as or generally similar to like components disclosed herein. Unlike the SAW device 2, the SAW device 4 does not include the intermediate layer 11.

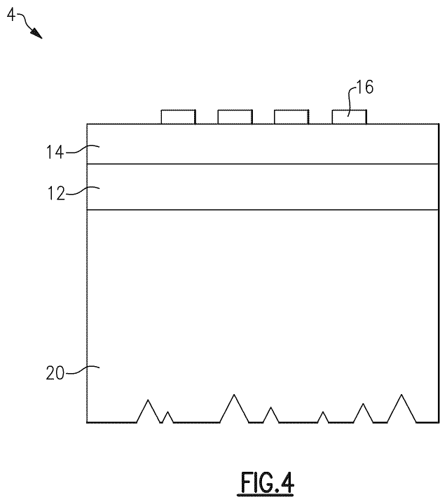

SAW devices disclosed herein can be formed in any suitable manner. For example, a method of manufacturing a SAW device according to an embodiment can include providing a multi-layer piezoelectric substrate including a support substrate having a first side and second side and a piezoelectric layer over the second side of the support substrate, forming an interdigital transducer electrode in electrical communication with the piezoelectric layer, and roughening the first side of the support substrate to make a surface roughness of the first side greater than a surface roughness of the second side. The roughening process is described with respect to FIGS. 5A and 5B.

FIG. 5A is a schematic cross-sectional side view of a structure that includes a support substrate 20 prior to roughening, an intermediate structure including intermediate layers 11, 12, a piezoelectric layer 14, and an interdigital transducer (IDT) electrode 16. FIG. 5B is a schematic cross-sectional side view of the structure of FIG. 5A after roughening. The first side 20a of the support substate 20 can be roughened by way of grinding. For example, the grinding process can utilize a grinding wheel or grinding disc 50 to grind the first side 20a of the support substrate 20. The grinding disc 50 can rotate and grind the first side 20a of the support substrate 20. Roughening the first side 20a of the support substrate 20 can include forming grooves on the first side 20a of the support substrate 20.

After the grinding process, the method can also include a singulation or dicing process. For example, the singulation process can include mechanical dicing, laser dicing, plasma dicing, etc. In some embodiments, the SAW device 2 can be singulated by way of dicing along a singulation line SL shown in FIG. 5B.

An MPS SAW device including any suitable combination of features disclosed herein can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more MPS SAW resonators disclosed herein. FR1 can be from 410 MHz to 7.125 GHz, for example, as specified in a current 5G NR specification. In 5G applications, the thermal dissipation of the MPS SAW resonators disclosed herein can be advantageous. For example, such thermal dissipation can be desirable in 5G applications with a higher time-division duplexing (TDD) duty cycle compared to fourth generation (4G) Long Term Evolution (LTE). At the same time, the MPS SAW resonators disclosed herein can reduce back reflection from the support substrate and maintain a desirable frequency response at higher frequencies for a filter that includes the MPS SAW resonators. In 5G applications, this feature can help with meeting output of band specifications, for example, for carrier aggregation applications. One or more MPS SAW resonators in accordance with any suitable principles and advantages disclosed herein can be included in a filter arranged to filter a radio frequency signal in a 4G LTE operating band and/or in a filter having a passband that includes a 4G LTE operating band and a 5G NR operating band.

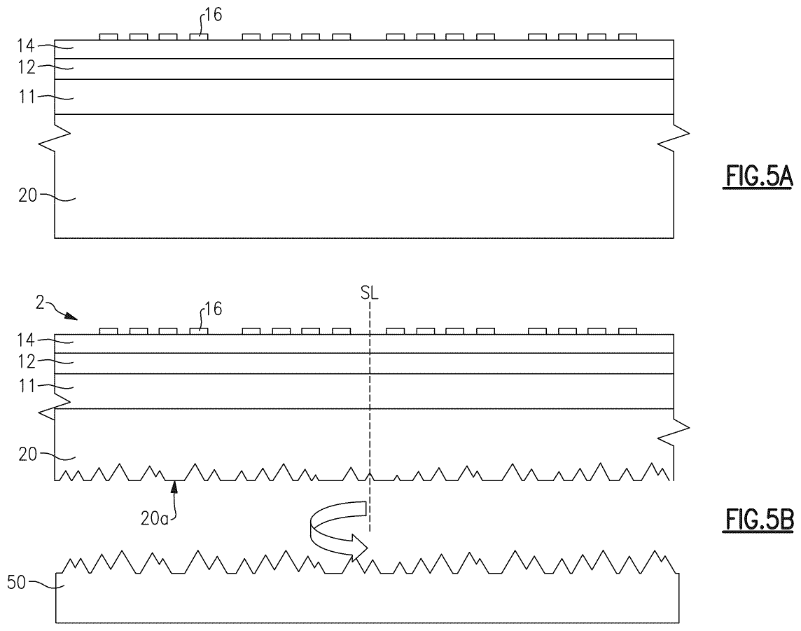

FIG. 6A is a schematic diagram of an example transmit filter 100 that includes surface acoustic wave devices according to an embodiment. The transmit filter 100 can be a band pass filter. The illustrated transmit filter 100 is arranged to filter a radio frequency signal received at a transmit port TX and provide a filtered output signal to an antenna port ANT. Some or all of the SAW resonators TS1 to TS7 and/or TP1 to TP5 can be SAW devices in accordance with any suitable principles and advantages disclosed herein. For instance, one or more of the SAW resonators of the transmit filter 100 can be coupled by way of a conductive structure disclosed herein. Any suitable number of series SAW resonators and shunt SAW resonators can be included in a transmit filter 100.

FIG. 6B is a schematic diagram of a receive filter 105 that includes surface acoustic wave devices according to an embodiment. The receive filter 105 can be a band pass filter. The illustrated receive filter 105 is arranged to filter a radio frequency signal received at an antenna port ANT and provide a filtered output signal to a receive port RX. Some or all of the SAW resonators RS1 to RS8 and/or RP1 to RP6 can be SAW resonators in accordance with any suitable principles and advantages disclosed herein. Any suitable number of series SAW resonators and shunt SAW resonators can be included in a receive filter 105.

Although FIGS. 6A and 6B illustrate example ladder filter topologies, any suitable filter topology can include a conductive structure in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

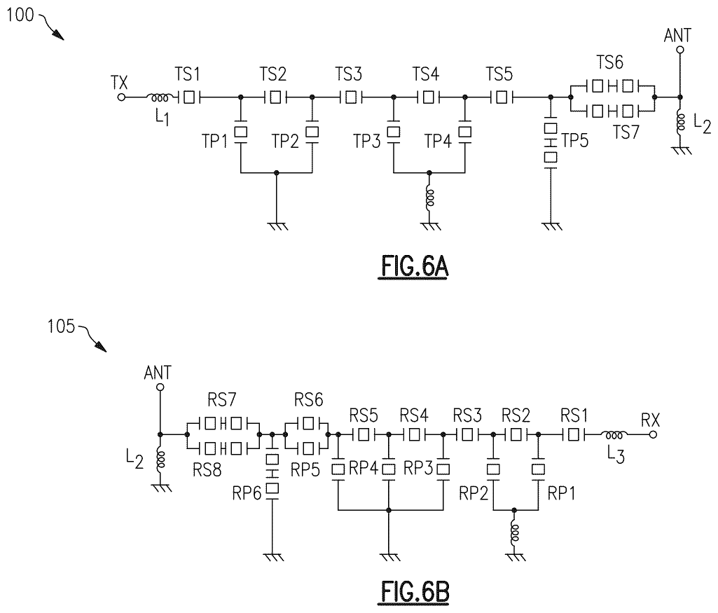

FIG. 7 is a schematic diagram of a radio frequency module 175 that includes a surface acoustic wave component 176. The illustrated radio frequency module 175 includes the SAW component 176 and other circuitry 177. The SAW component 176 can include one or more SAW resonators with any suitable combination of features of the SAW resonators disclosed herein. The SAW component 176 can include a SAW die that includes SAW resonators.

The SAW component 176 shown in FIG. 7 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 178B can serve, for example, as an input contact and an output contact. The SAW component 176 and the other circuitry 177 are on a common packaging substrate 180 in FIG. 7. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

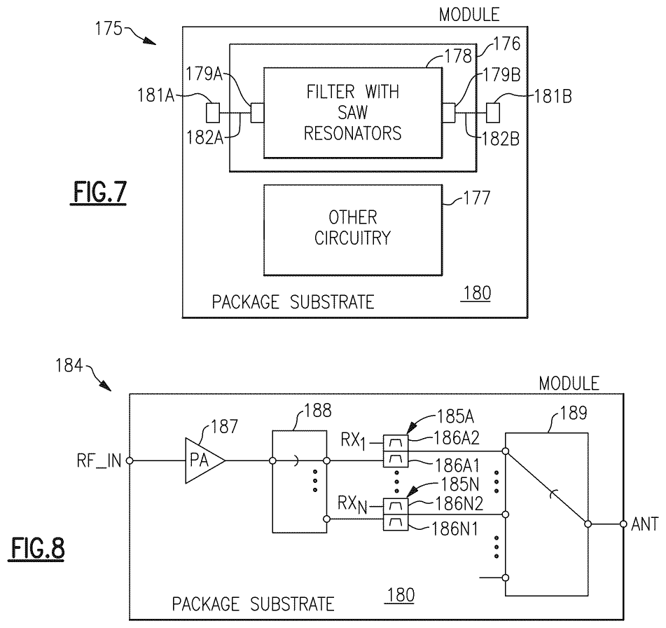

FIG. 8 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 8 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

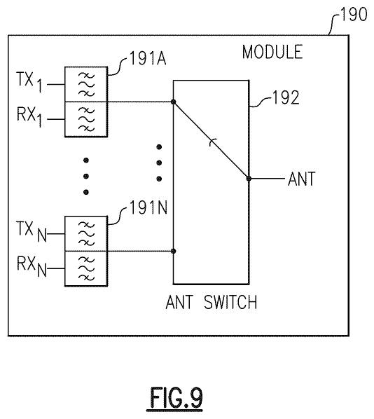

FIG. 9 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

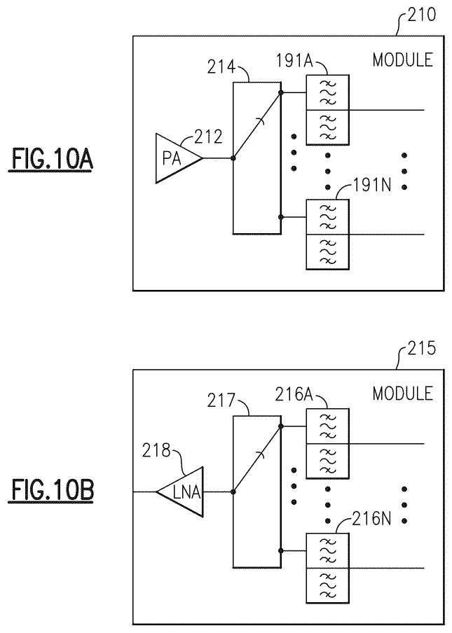

FIG. 10A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 10B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments, one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments, a plurality of low noise amplifiers can be implemented. The module 215 can include diversity receive features in certain applications.

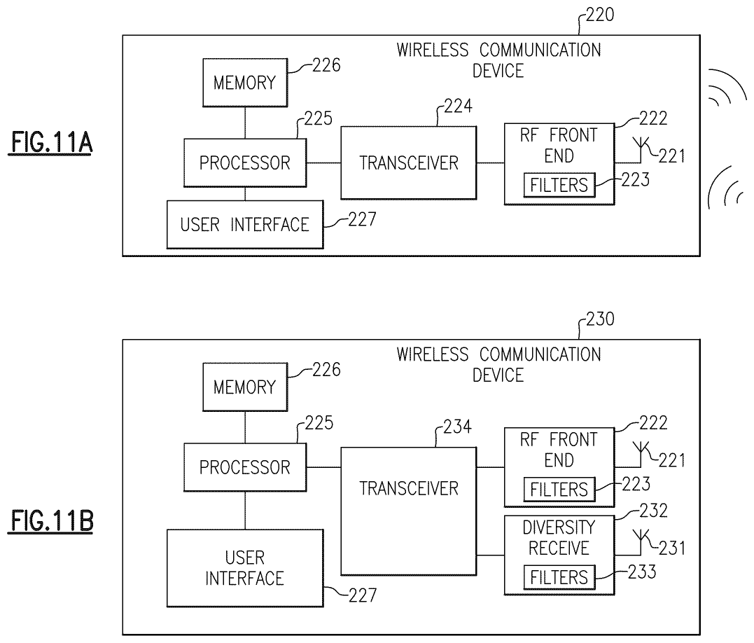

FIG. 11A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 11B is a schematic diagram of a wireless communication device 230 that includes filters 223 in a radio frequency front end 222 and a second filter 233 in a diversity receive module 232. The wireless communication device 230 is like the wireless communication device 220 of FIG. 11A, except that the wireless communication device 230 also includes diversity receive features. As illustrated in FIG. 11B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A surface acoustic wave device comprising:
a support substrate having a first side and second side, the first side having a surface roughness greater than a surface roughness of the second side;
a piezoelectric layer over the second side of the support substrate; and
an interdigital transducer electrode in electrical communication with the piezoelectric layer.

2. The surface acoustic wave device of claim 1 wherein the surface roughness of the first side is in a range between 100 nanometers and 1000 nanometers.

3. The surface acoustic wave device of claim 1 wherein the surface roughness of the first side is in a range between 100 nanometers and 750 nanometers.

4. The surface acoustic wave device of claim 1 wherein the surface roughness of the first side is in a range between 200 nanometers and 750 nanometers.

5. The surface acoustic wave device of claim 1 wherein the surface roughness of the first side is 10 to 10000 times greater than the surface roughness of the second side.

6. The surface acoustic wave device of claim 1 wherein the surface roughness of the first side is 100 to 10000 times greater than the surface roughness of the second side.

7. The surface acoustic wave device of claim 1 wherein the first side of the support substrate includes grooves.

8. The surface acoustic wave device of claim 1 further comprising an intermediate structure between the support substrate and the piezoelectric layer.

9. The surface acoustic wave device of claim 8 wherein the intermediate structure includes a trap-rich layer.

10. The surface acoustic wave device of claim 8 wherein the intermediate structure includes a functional layer.

11. A surface acoustic wave die comprising:
a support substrate having a first side and second side, the first side having a surface roughness greater than a surface roughness of the second side;
a piezoelectric layer over the second side of the support substrate; and
a plurality of interdigital transducer electrodes in electrical communication with the piezoelectric layer.

12. The surface acoustic wave die of claim 11 wherein the surface roughness of the first side is in a range between 100 nanometers and 1000 nanometers.

13. The surface acoustic wave die of claim 11 wherein the plurality of interdigital transducer electrodes include two to fifty interdigital transducer electrodes.

14. The surface acoustic wave die of claim 11 wherein the surface roughness of the first side is 10 to 10000 times greater than the surface roughness of the second side.

15. The surface acoustic wave die of claim 11 further comprising an intermediate structure between the support substrate and the piezoelectric layer, wherein the intermediate structure includes a trap-rich layer and a functional layer.

16. A method of manufacturing a surface acoustic wave device, the method comprising:
providing a multi-layer piezoelectric substrate including a support substrate having a first side and second side and a piezoelectric layer over the second side of the support substrate;
forming an interdigital transducer electrode in electrical communication with the piezoelectric layer; and
roughening the first side of the support substrate to make a surface roughness of the first side greater than a surface roughness of the second side.

17. The method of claim 16 wherein roughening the first side of the support substrate includes grinding.

18. The method of claim 16 wherein roughening the first side of the support substrate makes the surface roughness of the first side to be in a range between 100 nanometers and 1000 nanometers.

19. The method of claim 16 wherein roughening the first side of the support substrate makes the surface roughness of the first side to be in a range between 10 to 10000 times greater than the surface roughness of the second side.

20. The method of claim 16 wherein roughening the first side of the support substrate includes forming grooves on the first side of the support substrate.
